(19) United States
(12) Patent Application Publication
(10) Pub. No.: US 2026/0372061 A1
(43) Pub. Date: Nov. 19, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Kuei-Chun Hung, Hsinchu City (TW); Shih-Chieh Hsu, New Taipei City (TW); Yu-Ping Wang, Hsinchu City (TW); Chuan-Lan Lin, Chiayi City (TW); Teng-Chuan Hu, Tainan City (TW); Chun-Hung Chen, Tainan City (TW)

(73) Assignee: UNITED MICROELECTRONICS CORP., Hsin-Chu City (TW)

(21) Appl. No.: 19/239,894

(22) Filed: Jun. 16, 2025

(30) Foreign Application Priority Data
May 19, 2025 (TW) 114118649

(51) Int. Cl. H10W 20/41; H10W 72/00; H10W 72/90; H10W 80/00; H10W 90/00

(52) U.S. Cl. CPC H10W 20/435; H10W 72/019; H10W 72/921; H10W 72/923; H10W 72/942; H10W 72/952; H10W 80/312; H10W 80/327; H10W 90/792

(57) ABSTRACT

A method for fabricating a semiconductor device includes the steps of first forming a first inter-metal dielectric (IMD) layer on a substrate, forming a first metal interconnection in the first IMD layer, forming a metal oxide layer on the first IMD layer and the first metal interconnection, forming a stop layer on the metal oxide layer, forming a second IMD layer on the stop layer, forming a passivation layer on the second IMD layer, and then forming a second metal interconnection in the second IMD layer to connect to the first metal interconnection.

### BACKGROUND OF THE INVENTION

### FIELD OF THE INVENTION

The present invention relates to a method for manufacturing a semiconductor device, and more particularly to a method for forming a metal oxide layer on the surface of an inter-metal dielectric (IMD) layer prior to fabricating a hybrid bond.

### DESCRIPTION OF THE PRIOR ART

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating a semiconductor device includes the steps of first forming a first inter-metal dielectric (IMD) layer on a substrate, forming a first metal interconnection in the first IMD layer, forming a metal oxide layer on the first IMD layer and the first metal interconnection, forming a stop layer on the metal oxide layer, forming a second IMD layer on the stop layer, forming a passivation layer on the second IMD layer, and then forming a second metal interconnection in the second IMD layer to connect to the first metal interconnection.

According to another aspect of the present invention, a semiconductor device includes a first inter-metal dielectric (IMD) layer on a substrate, a first metal interconnection in the first IMD layer, and a metal oxide layer on the first IMD layer and the first metal interconnection.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a semiconductor device according to an embodiment of the present invention.

FIG. 6 illustrates a schematic structural view of a semiconductor device according to one embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-5, FIGS. 1-5 are schematic diagrams illustrating a method for fabricating a semiconductor device according to an embodiment of the present invention. As shown in FIG. 1, a substrate 12 composed of a semiconductor material is first provided. The substrate 12 may be selected from for example, a silicon substrate, an epitaxial silicon substrate, a silicon carbide substrate, or even a silicon-on-insulator (SOI) substrate. Such material selections are within the scope of the present invention. In the present embodiment, the substrate 12 may be used in subsequent processes to fabricate various devices such as medium-voltage (MV) devices, high-voltage (HV) devices, pixel circuits, low-voltage (LV) devices for low-voltage driver circuits, and/or graphics processing units (GPUs).

A front-end-of-line (FEOL) process and a back-end-of-line (BEOL) process are then performed on the substrate 12. In the present embodiment, the FEOL process may include the formation of active and/or passive devices on the substrate 12 such as metal-oxide-semiconductor (MOS) transistors, oxide semiconductor field-effect transistors (OS FETs), Fin field-effect transistors (FinFETs), or other device structures depending on the process or product requirements. The BEOL process may then be performed over these active and/or passive devices to form metal interconnection structures such as inter-metal dielectric (IMD) layers and metal interconnections. By way of example, in the fabrication of a MOS transistor, the FEOL process may include forming a gate structure on the substrate, sidewall spacers (not shown) on the sidewalls of the gate structure, and source/drain regions in the substrate on both sides of the sidewall spacers. The gate structure may include polysilicon or metal materials, the sidewall spacers may include dielectric materials such as silicon oxide or silicon nitride, and the source/drain regions may include different dopants according to the conductivity type of the transistor, for example, P-type or N-type dopants.

Next, an interlayer dielectric (ILD) layer (not shown) is formed over the substrate 12 covering the MOS transistor or other active devices, followed by the formation of contact plugs and metal interconnections in the BEOL process. A plurality of contact plugs are formed within the interlayer dielectric layer to connect the source/drain regions and the gate structure, an IMD layer 14 is disposed on the ILD layer, and metal interconnections 16 are formed within the IMD layer 14 and connected to the contact plugs. The uppermost metal interconnections 16 on the front side of substrate 12 may serve as a bonding pad for subsequent direct bond interconnect (DBI) or hybrid bond connections, which may be coupled with direct bond interconnects on another wafer in subsequent processes. In this embodiment, the ILD layer and the IMD layer 14 may include oxides such as but not limited to tetraethyl orthosilicate (TEOS). The contact plugs and metal interconnections 16 may include aluminum (Al), chromium (Cr), copper (Cu), tantalum (Ta), molybdenum (Mb), tungsten (W), or combinations thereof, but are not limited thereto.

According to an embodiment of the present invention, the metal interconnections 16 may be embedded within the IMD layer 14 by either a single damascene or dual damascene process. The metal interconnections 16 may include via conductors and/or trench conductors, and may further include a barrier layer 18 and a metal layer 20. For example, the barrier layer 18 may be selected from the group consisting of titanium (Ti), titanium nitride (TiN), tantalum (Ta), and tantalum nitride (TaN), while the metal layer 20 may be selected from the group consisting of tungsten (W), copper (Cu), aluminum (Al), titanium aluminum alloy (TiAl), and cobalt tungsten phosphide (CoWP), but is not limited thereto.

Next, a metal oxide layer 22 is formed on the IMD layer 14 and metal interconnection 16, in which the metal oxide layer 22 completely covers the IMD layer 14 and the metal interconnection 16. In the present embodiment, the metal oxide layer 22 preferably includes aluminum oxide (Al₂O₃), which can be used to isolate oxygen after subsequent hybrid bonding formation.

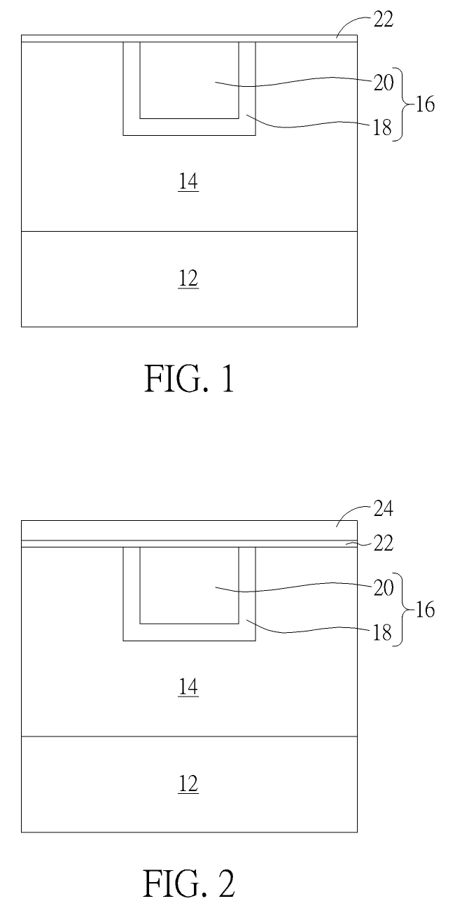

Subsequently, as shown in FIG. 2, a stop layer 24 is formed on the metal oxide layer 22. The stop layer 24 preferably includes silicon carbonitride (SiCN), but is not limited thereto. According to other embodiments of the present invention, the stop layer 24 may alternatively include a nitrogen-doped carbide (NDC) layer or silicon nitride (SiN), all of which are within the scope of the present invention.

As illustrated in FIG. 3, another IMD layer 26 is then formed on the stop layer 24. According to one embodiment of the present invention, the IMD layer 26 and the IMD layer 14 may include same or different materials. For example, the IMD layer 26 may include oxides such as an ultra-low-k dielectric layer, which may include porous dielectric materials including but not limited to silicon oxycarbide (SiOC) or hydrogenated silicon oxycarbide (SiOCH), all of which are encompassed by the present invention.

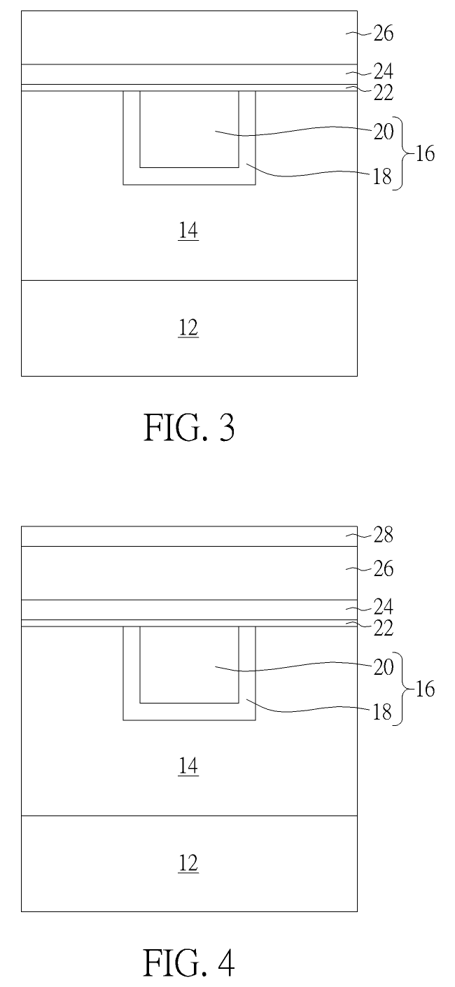

Next, as shown in FIG. 4, a passivation layer 28 is formed on the surface of the IMD layer 26. In the present embodiment, the passivation layer 28 may include the same or different materials as the underlying stop layer 24, such as silicon carbonitride (SiCN), but is not limited thereto. According to other embodiments of the present invention, the passivation layer 28 may alternatively include a nitrogen-doped carbide (NDC) layer or silicon nitride (SiN), which are within the scope of the present invention.

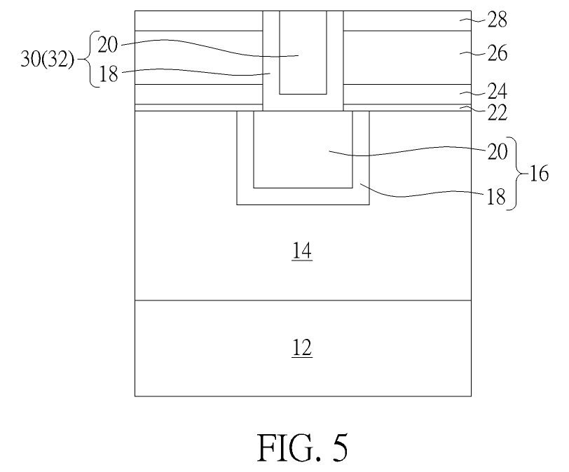

Next, as shown in FIG. 5, another metal interconnection 30 is formed within the IMD layer 26 to serve as a hybrid bond 32 electrically connecting to the metal interconnect 16. More specifically, the method for forming the metal interconnection 30 at this stage includes a photo-etching process to remove portions of the passivation layer 28, the IMD layer 26, the stop layer 24, and the metal oxide layer 22 to form a contact hole (not shown) exposing the surface of the underlying metal interconnect 16. Subsequently, the contact hole is filled with a metal or conductive material, for example, a barrier layer 18 including titanium (Ti), titanium nitride (TiN), tantalum (Ta), tantalum nitride (TaN), etc., and a metal layer 20 selected from tungsten (W), copper (Cu), aluminum (Al), titanium-aluminum alloy (TiAl), cobalt tungsten phosphide (CoWP), or combinations thereof. Thereafter, a planarizing process such as chemical mechanical polishing (CMP) is performed to remove excess metal material thereby forming the metal interconnection 30 within the contact hole electrically connected to the metal interconnection 16. This completes fabrication of a semiconductor device according to one embodiment of the present invention.

Referring again to FIG. 5, which discloses a schematic structural view of a semiconductor device according to one embodiment of the present invention. As shown in FIG. 5, the semiconductor device primarily includes an IMD layer 14 disposed on a substrate 12, a metal interconnect 16 disposed within the IMD layer 14, a metal oxide layer 22 disposed on the IMD layer 14, a stop layer 24 disposed on the metal oxide layer 22, another IMD layer 26 disposed on the stop layer 24, a passivation layer 28 disposed on the IMD layer 26, and a metal interconnection 30 disposed within the passivation layer 28, the IMD layer 26, the stop layer 24, and the metal oxide layer 22 electrically connected to or directly contacting the metal interconnection 16.

In detail, the width of the metal interconnection 30 is preferably smaller than the width of the underlying metal interconnection 16. The top surface of the metal interconnection 30 is preferably flush with the top surface of the passivation layer 28 on both sides. The stop layer 24 and the passivation layer 28 may have the same or different thicknesses, and the thickness of the metal oxide layer 22 is preferably less than that of the stop layer 24 and/or the passivation layer 28. According to one embodiment of the present invention, the thickness of the metal oxide layer 22 is preferably less than half, or even less than one-third of the thickness of the stop layer 24 and/or the passivation layer 28. Alternatively, the thickness of the stop layer 24 and/or the passivation layer 28 may be greater than two, three, four, or even five times the thickness of the metal oxide layer 22, all of which fall within the scope of the present invention.

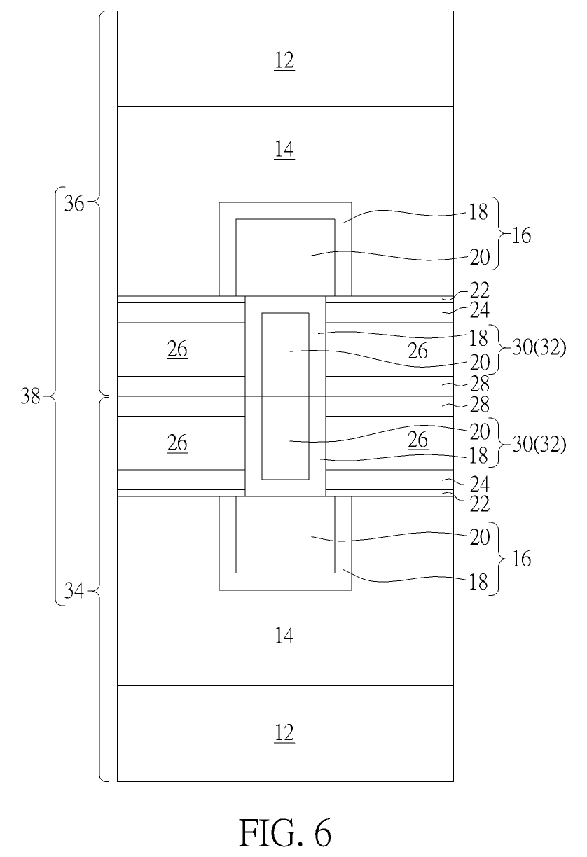

Referring further to FIG. 6, which discloses a schematic structural view of a semiconductor device according to one embodiment of the present invention. As shown in FIG. 6, the present invention may first provide a first wafer 34 or first interposer layer made of the substrate 12, IMD layers 14 and 26, and metal interconnections 16 and 30 based on the processes described in FIGS. 1-5. The metal interconnection 30 within the IMD layer 26 serves as a hybrid bond 32 for bonding with another wafer. For example, according to the processes of FIGS. 1-5, a second wafer 36 or second interposer layer made of substrate 12, IMD layers 14 and 26, and metal interconnections 16 and 30 may be formed. The second wafer 36 may then be flipped and subjected to a hybrid bonding process to bond the first wafer 34 and the second wafer 36 thereby forming a stacked structure 38. Subsequently, additional elements such as through-silicon vias (TSVs), bumps, solder balls, or redistribution layers (RDL) may be formed according to process or product requirements. All these are encompassed within the scope of the present invention.

In summary, the present invention discloses a method for fabricating a hybrid bond, in which the method includes forming an IMD layer 14 on a substrate 12, forming a metal interconnection 16 within the IMD layer 14, forming a metal oxide layer 22 on the IMD layer 14 and the metal interconnection 16, forming a stop layer 24 on the metal oxide layer 22, forming another IMD layer 26 on the stop layer 24, forming a passivation layer 28 on the IMD layer 26, and forming another metal interconnection 30 within the IMD layer 26 electrically connected to the metal interconnection 16. The metal interconnection 30 serves as a hybrid bond 32 to be bonded with another wafer or interposer in subsequent processes. According to a preferred embodiment of the present invention, a metal oxide layer composed, for example, of aluminum oxide is additionally formed on the surfaces of the IMD layers on both sides of the hybrid bond to effectively isolate oxygen ingress into the device, thereby ensuring the overall stability and performance of the product.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a first inter-metal dielectric (IMD) layer on a substrate;
forming a first metal interconnection in the first IMD layer; and
forming a metal oxide layer on the first IMD layer and the first metal interconnection.

2. The method of claim 1, further comprising:
forming a stop layer on the metal oxide layer;
forming a second IMD layer on the stop layer;
forming a passivation layer on the second IMD layer; and
forming a second metal interconnection in the second IMD layer to connect to the first metal interconnection.

3. The method of claim 2, further comprising:
removing the passivation layer, the second IMD layer, the stop layer, and the metal oxide layer to form a contact hole; and
forming the second metal interconnection in the contact hole.

4. The method of claim 2, wherein the first metal interconnection and the second metal interconnection comprise same material.

5. The method of claim 2, wherein a width of the second metal interconnection is less than a width of the first metal interconnection.

6. A semiconductor device, comprising:
a first inter-metal dielectric (IMD) layer on a substrate;
a first metal interconnection in the first IMD layer; and
a metal oxide layer on the first IMD layer and the first metal interconnection.

7. The semiconductor device of claim 6, further comprising:
a stop layer on the metal oxide layer;
a second IMD layer on the stop layer;
a passivation layer on the second IMD layer; and
a second metal interconnection in the passivation layer, the second IMD layer, the stop layer, and the metal oxide layer to connect to the first metal interconnection.

8. The semiconductor device of claim 7, wherein the first metal interconnection and the second metal interconnection comprise same material.

9. The semiconductor device of claim 7, wherein a width of the second metal interconnection is less than a width of the first metal interconnection.
